(19) United States
(12) Patent Application Publication
(10) Pub. No.: US 2021/0179649 A1
(43) Pub. Date: Jun. 17, 2021

(54) ORGANIC METAL COMPOUND AND ORGANIC LIGHT-EMITTING DEVICE

(71) Applicant: INDUSTRIAL TECHNOLOGY RESEARCH INSTITUTE, Hsinchu (TW)

(72) Inventors: Jia-Lun LIOU, Hengshan Township (TW); Po-Jung HSU, Taipei City (TW); Han-Cheng YEH, Taipei City (TW); Mei-Rurng TSENG, Hsinchu City (TW)

(73) Assignee: INDUSTRIAL TECHNOLOGY RESEARCH INSTITUTE, Hsinchu (TW)

(21) Appl. No.: 16/915,261

(22) Filed: Jun. 29, 2020

(30) Foreign Application Priority Data
Dec. 13, 2019 (TW) 108145771

(51) Int. Cl. C07F 15/00; H01L 51/00

(52) U.S. Cl. CPC C07F 15/0033; H01L 51/0085

(57) ABSTRACT

Organic metal compounds, and organic light-emitting devices employing the same are provided. The organic metal compound has a chemical structure of Formula (I):

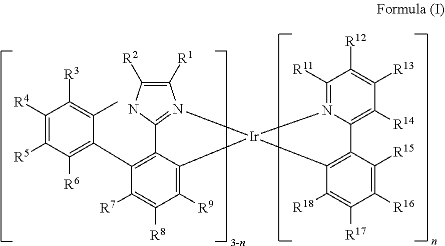

The definitions of R¹-R¹⁸ and n are as defined in specification. The organic light-emitting device includes a pair of electrodes; and an organic light-emitting element, disposed between the electrodes, wherein the organic light-emitting element includes the aforementioned organic metal compound.

### CROSS REFERENCE TO RELATED APPLICATIONS

The application is based on, and claims priority of Taiwan Application Serial Number 108145771, filed on Dec. 13, 2019, the disclosure of which is hereby incorporated by reference herein in its entirety.

### TECHNICAL FIELD

The disclosure relates to an organic metal compound and an organic light-emitting device employing the same.

### BACKGROUND

An organic light-emitting diode (OLED) is a light-emitting diode employing an organic electroluminescent layer as an active layer. OLED display devices have high luminescent efficiency and long operating lifespans. Due to their characteristics of spontaneous emission, devices using organic light-emitting diodes do not need a back-light source, marking an improvement over liquid-crystal displays.

Organic light-emitting devices are generally composed of a light-emission layer sandwiched between a pair of electrodes. When an electric field is applied to the electrodes, the cathode injects electrons into the light-emission layer and the anode injects holes into the light-emission layer. When the electrons recombine with the holes in the light-emission layer, excitons are formed. Recombination of the electron and hole results in light emission.

Depending on the spin states of the hole and electron, the exciton, which results from the recombination of the hole and electron, can have either a triplet or singlet spin state. Luminescence from a singlet exciton results in fluorescence whereas luminescence from a triplet exciton results in phosphorescence. The emissive efficiency of phosphorescence is three times that of fluorescence. Therefore, it is crucial to develop highly efficient phosphorescent material, in order to increase the emissive efficiency of an OLED.

### SUMMARY

According to embodiments of the disclosure, the disclosure provides an organic metal compound having a structure of Formula (I):

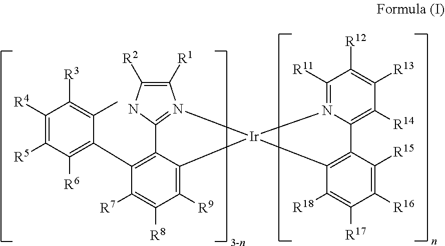

wherein R¹ or R² is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸ or R⁹ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ are independently C₁₋₈ alkyl group; R¹¹, R¹², R¹³, R¹⁴, R¹⁵, R¹⁶, R¹⁷, or R¹⁸ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ are independently C₁₋₈ alkyl group; and n meets one of following conditions (1), (2) and (3):

(1) n is 0, and at least one of R³, R⁴, R⁵, R⁶, R⁷, R⁸ and R⁹ is —Si(R¹⁹)₃, wherein R¹⁹ are independently C₁₋₈ alkyl group;

(2) n is 1 or 2, and at least one of R³, R⁴, R⁵, R⁶, R⁷, R⁸, R⁹, R¹¹, R¹², R¹³, and R¹⁴ is —Si(R¹⁹)₃, wherein R¹⁹ are independently C₁₋₈ alkyl group; and

(3) n is 3, and at least one of R¹¹, R¹², R¹³, and R¹⁴ is —Si(R¹⁹)₃, wherein R¹⁹ are independently C₁₋₈ alkyl group.

According to another embodiment of the disclosure, the disclosure provides an organic light-emitting device. The device includes a pair of electrodes; and an organic light-emitting element, disposed between the electrodes, wherein the organic light-emitting element comprises the aforementioned organic metal compound.

A detailed description is given in the following embodiments with reference to the accompanying drawings.

### BRIEF DESCRIPTION OF THE DRAWINGS

FIG. 1 is a cross-sectional view of the organic light-emitting device according to an embodiment of the disclosure.

### DETAILED DESCRIPTION

According to embodiments of the disclosure, the disclosure an organic metal compound having a structure of Formula (I):

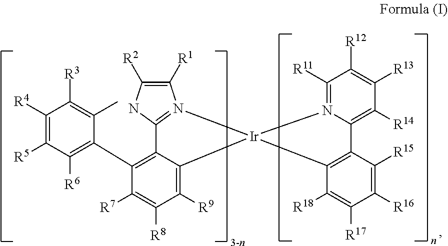

wherein R¹ or R² is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸ or R⁹ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ are independently C₁₋₈ alkyl group; R¹¹, R¹², R¹³, R¹⁴, R¹⁵, R¹⁶, R¹⁷, or R¹⁸ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ are independently C₁₋₈ alkyl group; and n meets one of following conditions (1), (2) and (3):

(1) n is 0, and at least one of R³, R⁴, R⁵, R⁶, R⁷, R⁸ and R⁹ is —Si(R¹⁹)₃, wherein R¹⁹ are independently C₁₋₈ alkyl group;

(2) n is 1 or 2, and at least one of R³, R⁴, R⁵, R⁶, R⁷, R⁸, R⁹, R¹¹, R¹², R¹³, and R¹⁴ is —Si(R¹⁹)₃, wherein R¹⁹ are independently C₁₋₈ alkyl group; and

(3) n is 3, and at least one of R¹¹, R¹², R¹³, and R¹⁴ is —Si(R¹⁹)₃, wherein R¹⁹ are independently C₁₋₈ alkyl group.

According to embodiments of the disclosure, C₁₋₈ alkyl group can be linear or branched alkyl group. For example, C₁₋₈ alkyl group can be methyl group, ethyl group, propyl group, iso-propyl group, n-butyl group, tert-butyl group, sec-butyl group, iso-butyl group, pentyl group or hexyl group. According to embodiments of the disclosure, C₁₋₈ haloalkyl group can be an alkyl group which a part of or all hydrogen atoms bonded on the carbon atom are replaced with halogen atoms, and C₁₋₈ haloalkyl group can be linear or branched haloalkyl group. For example, fluoromethyl group can be monofluoromethyl group, difluoromethyl group or trifluoromethyl group. According to embodiments of the disclosure, C₁₋₈ alkoxy group can be linear or branched alkoxy group. For example, C₁₋₈ alkoxy group can be methoxy group, ethoxy group, propoxy group, isopropoxy group, butoxy group, sec-butoxy group, iso-butoxy group, tert-butoxy group, pentyloxy group, or hexyloxy group.

According to embodiments of the disclosure, C₅₋₁₀ cycloalkyl group can be cyclopentyl group or cyclohexyl group. According to embodiments of the disclosure, C₆₋₁₂ aryl group can be phenyl group, biphenyl group, or naphthyl group. According to embodiments of the disclosure, —Si(R¹⁹)₃ can be trimethylsilyl group, triethylsilyl group, tripropylsilyl group, butyldimethylsilyl group, propyldimethylsilyl group or iso-butyldimethylsilyl group.

According to embodiments of the disclosure, R¹ or R² can be independently hydrogen, deuterium, deuterated methyl, deuterated ethyl, fluorine, methyl group, ethyl group, propyl group, isopropyl group, butyl group, sec-butyl group, iso-butyl group, tert-butyl group, pentyl group, hexyl group, fluoromethyl group, fluoroethyl group, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

According to embodiments of the disclosure, R³, R⁴, R⁵, R⁶, R⁷, R⁸, R⁹, R¹¹, R¹², R¹³, R¹⁴, or R¹⁵ is independently hydrogen, deuterium, deuterated methyl, deuterated ethyl, fluorine, methyl group, ethyl group, propyl group, isopropyl group, butyl group, sec-butyl group, iso-butyl group, tert-butyl group, pentyl group, hexyl group, fluoromethyl group, fluoroethyl group, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, naphthyl group, or trimethylsilyl group.

According to embodiments of the disclosure, R¹⁶, R¹⁷, or R¹⁸ can be independently hydrogen, deuterium, deuterated methyl, deuterated ethyl, fluorine, methyl group, ethyl group, propyl group, isopropyl group, butyl group, sec-butyl group, iso-butyl group, tert-butyl group, pentyl group, hexyl group, fluoromethyl group, fluoroethyl group, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

According to embodiments of the disclosure, R¹⁹ can be independently hydrogen, fluorine, methyl group, ethyl group, propyl group, n-butyl group, sec-butyl group, iso-butyl group, tert-butyl group, pentyl group, or hexyl group.

According to embodiments of the disclosure, since the organic metal compound having a structure represented by Formula (I) of the disclosure has at least one trialkylsilyl group, the organic metal compound can have a suitable highest occupied molecular orbital (HOMO) and lowest unoccupied molecular orbital (LUMO) energy gap, thereby facilitating the electrons recombining with the holes to form excitons, and exhibit superior electrochemical stability and thermal stability. As a result, the organic light-emitting device employing the organic metal compound can exhibit high operating lifespan and luminescent efficiency.

According to embodiments of the disclosure, the organic metal compound having a structure represented by Formula (I) of the disclosure can be

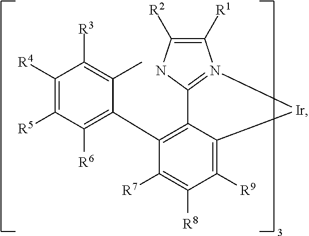

independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; and R³, R⁴, R⁵, R⁶, R⁷, R⁸, or R⁹ can be independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ can be independently C₁₋₈ alkyl group; and at least one of R³, R⁴, R⁵, R⁶, R⁷, R⁸, and R⁹ is —Si(R¹⁹)₃.

According to embodiments of the disclosure, the organic metal compound can be

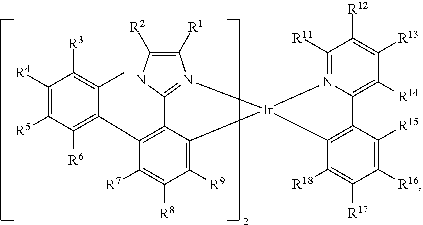

wherein R¹ or R² can be independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹¹, R¹², R¹³, R¹⁴, or R¹⁵ can be independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ can be independently C₁₋₈ alkyl group; and R¹⁶, R¹⁷, or R¹⁸ can be independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; and at least one of R³, R⁴, R⁵, R⁶, R⁷, R⁸, R⁹, R¹¹, R¹², R¹³, R¹⁴, and R¹⁵ is —Si(R¹⁹)₃.

According to embodiments of the disclosure, wherein R¹ or R² can be independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹¹, R¹², R¹³, R¹⁴, or R¹⁵ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ are independently C₁₋₈ alkyl group; and R¹⁶, R¹⁷, or R¹⁸ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; and at least one of R³, R⁴, R⁵, R⁶, R⁷, R⁸, and R⁹ is —Si(R¹⁹)₃.

According to embodiments of the disclosure, the organic metal compound can be

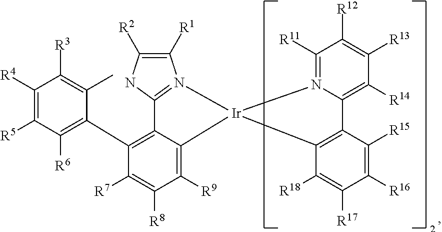

wherein R¹ or R² can be independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹¹, R¹², R¹³, R¹⁴, or R¹⁵ can be independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ are independently C₁₋₈ alkyl group; and R¹⁶, R¹⁷, or R¹⁸ can be independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; and at least one of R³, R⁴, R⁵, R⁶, R⁷, R⁸, R⁹, R¹¹, R¹², R¹³, R¹⁴ and R¹⁵ is —Si(R¹⁹)₃.

According to embodiments of the disclosure, wherein R¹ or R² can be independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹¹, R¹², R¹³, R¹⁴, or R¹⁵ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ are independently C₁₋₈ alkyl group; and R¹⁶, R¹⁷, or R¹⁸ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; and at least one of R³, R⁴, R⁵, R⁶, R⁷, R⁸, and R⁹ is —Si(R¹⁹)₃.

According to embodiments of the disclosure, the organic metal compound can be

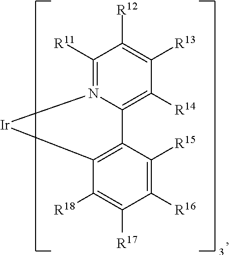

wherein R¹⁵, R¹⁶, R¹⁷ or R¹⁸ can be independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; R¹¹, R¹², R¹³, or R¹⁴ can be independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, and at least one of R¹¹, R¹², R¹³, and R¹⁴ is —Si(R¹⁹)₃, wherein R¹⁹ can be independently C₁₋₈ alkyl group.

The organic metal compounds having the structure represented by Formula (I) of the disclosure include the following compounds shown in Table 1 and the structures thereof are shown in Table 1.

TABLE 1

| | structure of organic metal compound |
|---|---|
| Example 1 | 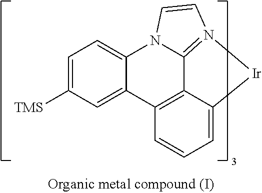 |
| Example 2 | 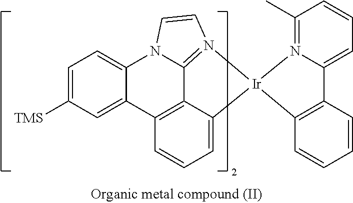 |
| Example 3 | 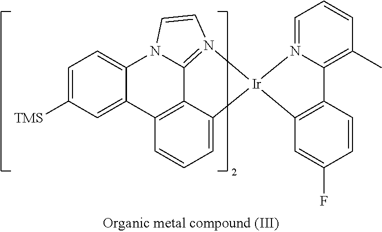 |
| Example 4 | 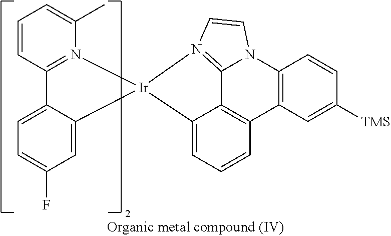 |
| Example 5 | 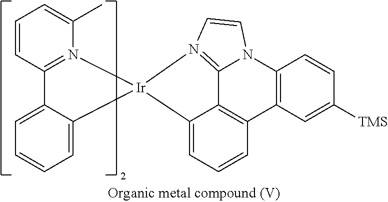 |
| Example 6 | 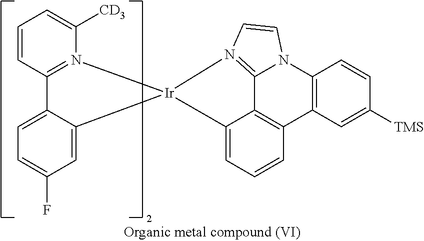 |
| Example 7 | 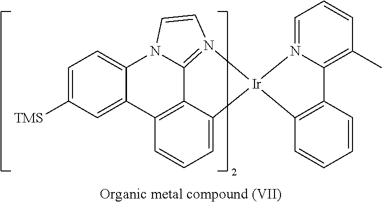 |
| Example 8 | 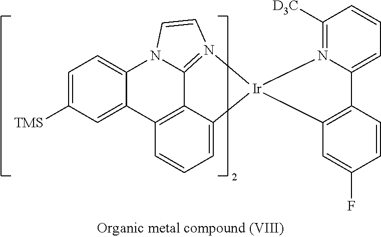 |
| Example 9 | 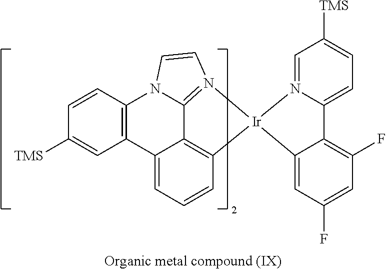 |

(TMS: (CH3)3Si- )

In order to clearly illustrate the method for preparing the organic metal compound of the disclosure, the preparation of compounds disclosed in Examples 1-9 are described in detail below.

### Example 1: Preparation of Organic Metal Compound (I)

2-bromoaniline (20.20 g, 117.4 mmol) and anhydrous tetrahydrofuran (THF) (500.0 mL) were added into a reaction bottle and then the reaction bottle was placed in an ice bath for 10 minutes. Next, n-butyl lithium (n-BuLi) (92.0 mL, 147.2 mmol) was added dropwise into the reaction bottle at 0° C. After stirring at 0° C. for 1 hour, 2-bromo-1,1-diethoxyethane (26.0 mL, 176.0 mmol) were added into the reaction bottle and the result was stirred at room temperature for 18 hours. The reaction was quenched by addition of water after complete reaction. The result was concentrated by rotary evaporator to remove THF. The result was extracted three times using ethyl acetate (EA) and water as the extraction solvent. Next, an organic phase was separated, dried, filtrated and purified by column chromatography (with ethyl acetate/n-hexane (120) as the extraction solvent) obtaining Compound (1)

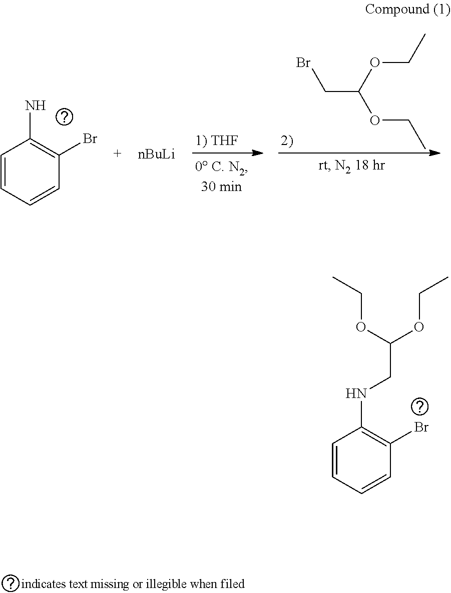

Compound (1) (27.26 g, 94.6 mmol) and dichloromethane (DCM) (240.0 mL) were added into a reaction bottle and then the reaction bottle was placed in an ice bath for 10 minutes. After adding trimethylamine (26.0 mL, 186.4 mmol) into the reaction bottle, benzoyl chloride (14.3 mL, 123.2 mmol) was added dropwise into the reaction bottle. After stirring for 10 minutes in the ice bath, the result was reacted at room temperature for 18 hours. The result was extracted using dichloromethane (DCM) and water as the extraction solvent. Next, an organic phase was separated, dried, filtrated and purified by column chromatography (with ethyl acetate/n-hexane (1:15) as the extraction solvent), obtaining Compound (2).

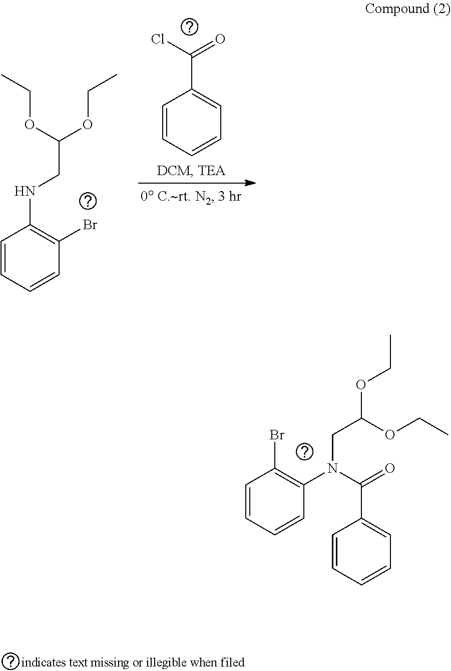 [SMILES: CCOC(CNc1ccccc1Br)OCC ; O=C(Cl)c1ccccc1 ; CCOC(CN(C(=O)c1ccccc1)c1ccccc1Br)OCC]

Compound (2) (25.90 g, 66.0 mmol), palladium (II) acetate (Pd(OAc)₂) (1.48 g, 6.6 mmol), tris(o-tolyl)phosphine (P(o-tolyl)₃) (4.02 g, 13.2 mmol), K₂CO₃ (18.25 g, 132 mmol) and dimethylformamide (DMF) (330.0 mL) were added into a reaction bottle The result was reacted at 130° C. under nitrogen gas for 1 hour. The result was filtrated by celite to remove the catalyst. The result was extracted using dichloromethane (DCM) and water as the extraction solvent. Next, an organic phase was separated, dried, filtrated and purified by column chromatography (with ethyl acetate/n-hexane (1:10) as the extraction solvent), obtaining Compound (3).

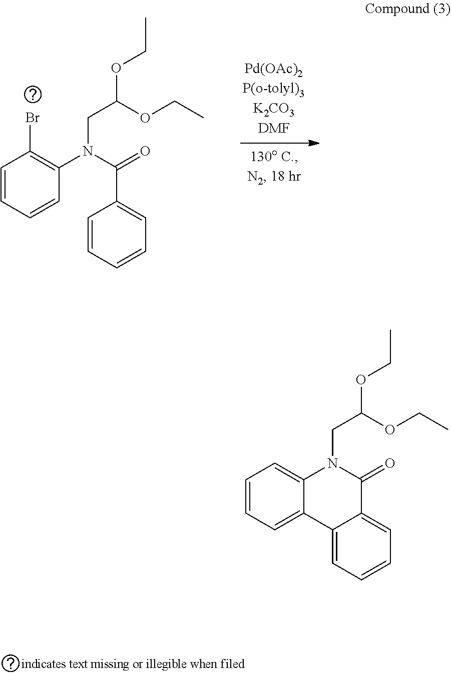 [SMILES: CCOC(CN(C(=O)c1ccccc1)c1ccccc1Br)OCC ; CCOC(Cn1c(=O)c2ccccc2c2ccccc21)OCC]

Compound (3) (18.40 g, 59.1 mmol) and acetic acid (100.0 mL) were added into a reaction bottle. After cooling the reaction bottle in an ice bath for 10 minutes, bromine water (7.7 mL, 150.5 mmol) was added into the reaction bottle. After stirring for 10 minutes, the reaction bottle was warmed to room temperature for 18 hours. After complete reaction, Na₂S₂O₃ (aq) was added into the reaction bottle to remove bromine water. The result was extracted using dichloromethane (DCM) and water as the extraction solvent. Next, an organic phase was separated, dried, filtrated and purified by column chromatography (with ethyl acetate/dichloromethane (1:3) as the extraction solvent), obtaining Compound (4).

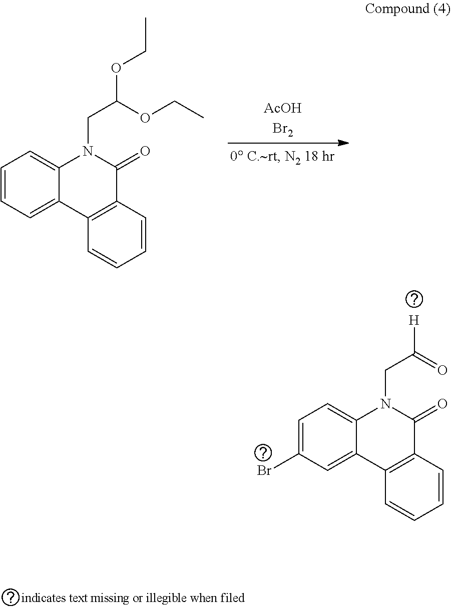 [SMILES: CCOC(Cn1c(=O)c2ccccc2c2ccccc21)OCC ; O=CCn1c(=O)c2ccccc2c2cc(Br)ccc21]

Compound (4) (5.90 g, 18.7 mmol) and acetic anhydride (56.0 mL) were added into a reaction bottle. After cooling the reaction bottle in an ice bath for 10 minutes, HBF₄ (aq) (4.0 mL, 32.1 mmol) was added dropwise into the reaction bottle. After complete addition, the result was reacted at room temperature for 18 hours. After reprecipitation with ethyl ether, the result was filtrated and then washed with ethyl ether, obtaining Compound (5).

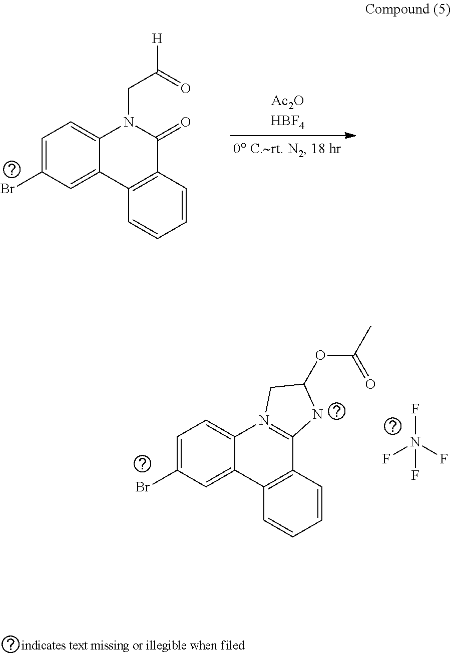

Compound (5) (7.73 g, 16.8 mmol), NH₄OAc (2.20 g, 28.5 mmol), ACN (50.4 mL) were added into a reaction bottle. After reacting at room temperature for 24 hours, HBF₄ (aq) (5.3 mL, 85.1 mmol) was added dropwise into the reaction bottle and then stirred in an ice bath for 10 minutes. Next, the reaction bottle was heated to 80° C. and then stirred for 18 hours. After neutralizing with K₂CO₃ (aq), the result was filtrated and then the filtered cake was washed with water and dried. Finally, the result was purified by column chromatography and subjected to a concentration, obtaining Compound (6).

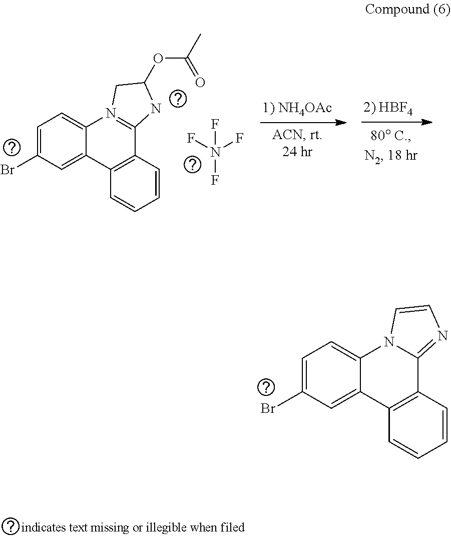

Compound (6) (1.00 g, 3.4 mmol) and anhydrous tetrahydrofuran (THF) (35.0 mL) were added into a reaction bottle, and then the reaction bottle was cooled to −78° C. Next, n-butyl lithium (n-BuLi) (2.5 mL, 4.0 mmol) was added dropwise into the reaction bottle. After stirring for 1 hour, trimethylsilyl chloride (TMSCl) (0.9 mL, 7.0 mmol) was added into the reaction bottle, and the result was reacted at room temperature for 18 hours. The reaction was quenched by addition of water after completion of reaction. The result was purified by column chromatography (with ethyl acetate/n-hexane (1:3) as the extraction solvent) and concentrated by rotary evaporator, obtaining Compound (7).

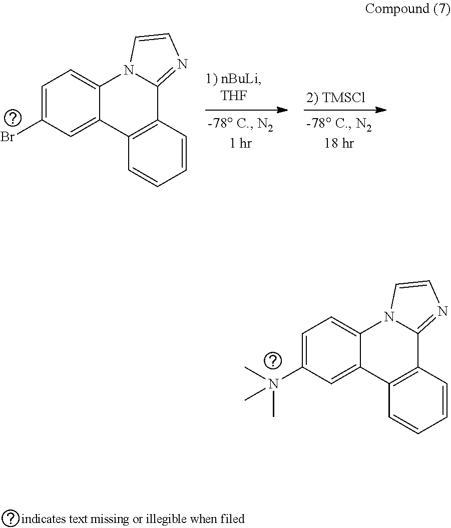

Next, Compound (7) (1.92 g, 6.6 mmol), and iridium trichloride, (IrCl₃) (0.89 g, 3 mmol), 2-methoxyethanol (24 ml), and water (8 ml) were added into the reaction bottle. Next, after removing moisture and purging nitrogen gas several times, the reaction bottle was heated to reflux (120° C.). After reacting for 24 hr, the reaction bottle was heated to room temperature, and then water was added into the reaction bottle. After filtrating, the filter cake was washed with water and n-hexane. After drying by a vacuum, Compound (8) was obtained. The synthesis pathway of the above reaction was as follows:

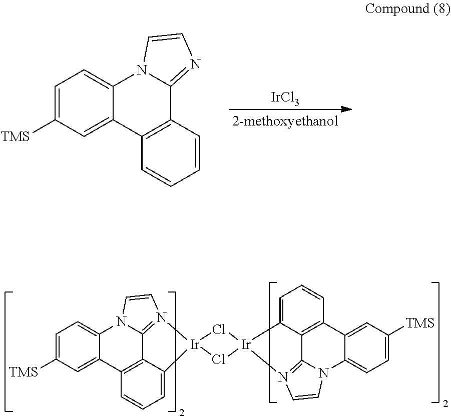

Next, compound (8) (1.61 g, 1 mmol), acetylacetone (0.4 g, 4 mmol), triethylamine (Et₃N) (0.5 ml, 4 mmol), and 2-methoxyethanol (10 ml) were added into a reaction bottle. Next, after removing moisture and purging nitrogen gas several times, the reaction bottle was heated to 120° C. After reacting for hours, the reaction bottle was warmed to room temperature. The result was subjected to a reprecipitation with water. After filtrating and washing the filter cake with water and hexane, the solid was dissolved with dichloromethane (CH₂Cl₂). Next, the result was extracted three times using dichloromethane (CH₂Cl₂) and water as the extraction solvent. An organic phase was separated, dried, filtrated and concentrated by rotary evaporator. Finally, the result was purified by column chromatography (with dichloromethane/n-hexane (1:5) as the extraction solvent), obtaining Compound (9). The synthesis pathway of the above reaction was as follows:

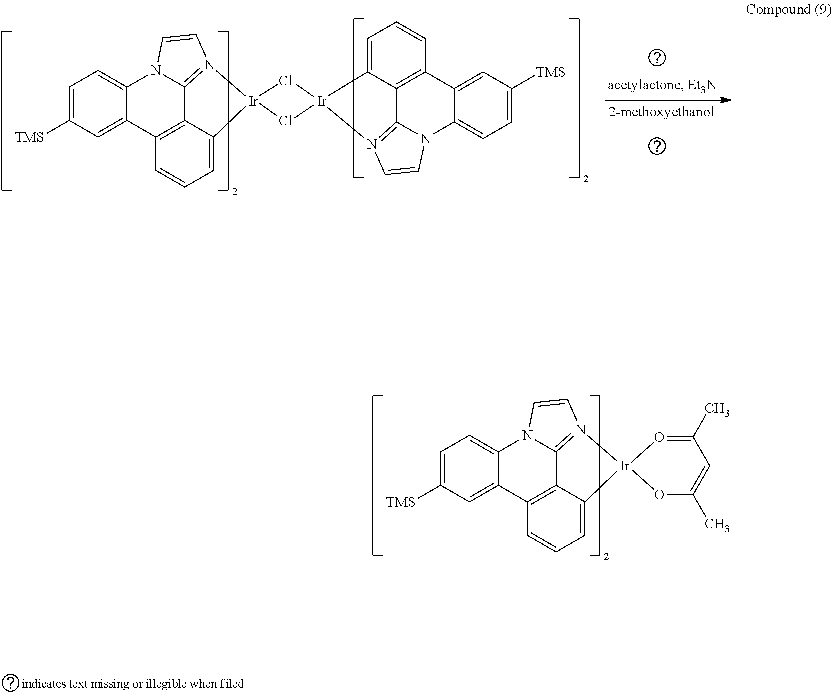

Next, Compound (9) (0.87 g, 1 mmol), Compound (7) (0.58 g, 2 mmol), and ethylene glycol (20 mL) were added into a reaction bottle. Next, the reaction bottle was heated to 160° C. under nitrogen atmosphere. After stirring 48 hours, the reaction bottle was cooled down to room temperature, and then water (30 mL) was added into the reaction bottle. After stirring, the precipitated solid was collected and washed with water. After drying, the solid was collected and purified by column chromatography (with dichloromethane/n-hexane (1:5) as the extraction solvent), obtaining Organic metal compound (I). The synthesis pathway of the above reaction was as follows:

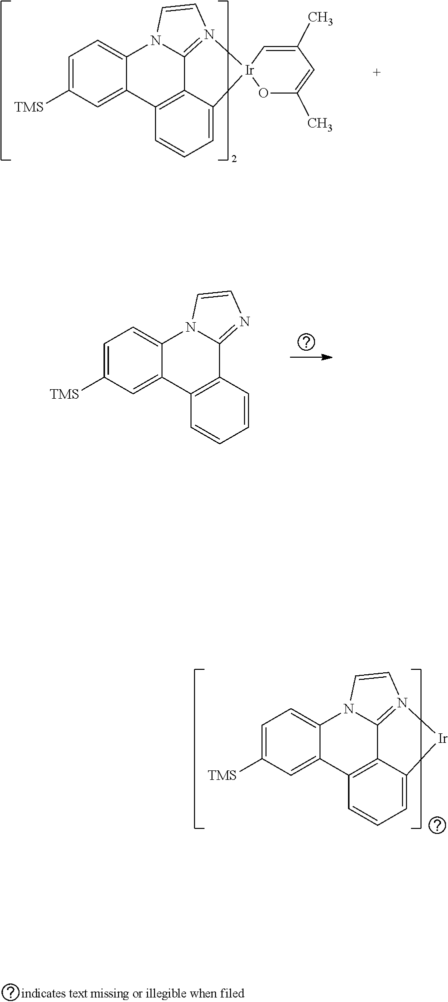

### Example 2: Preparation of Organic Metal Compound (II)

Compound (8) (1.61 g, 1 mmol) and CH₂Cl₂ were added into a reaction bottle. Next, AgOTf (0.56 g, 2.2 mmol) was dissolved in methanol (11 ml), and the result was added dropwise into the reaction bottle under nitrogen atmosphere. After reacting at room temperature for 12 hours, the result was filtrated and subjected to a concentration, obtaining Salt (A). The synthesis pathway of the above reaction was as follows:

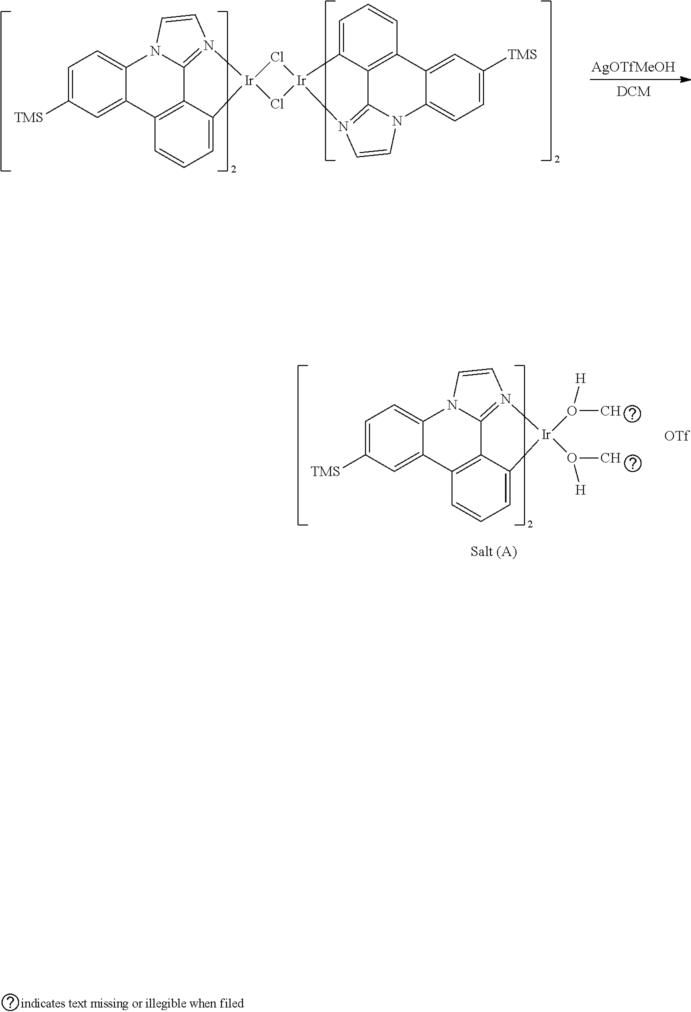

Next, Salt (A) (0.98 g, 1 mmol) and 2-methyl-6-phenylpyridine (0.25 g, 1.5 mmol) was added into a reaction bottle, and MeOH/EtOH (10 ml, 5/5) as solvent was added into the reaction bottle. After removing moisture, drying and purging nitrogen gas several times, the reaction bottle was heated to 90° C. After reacting for 12 hours, the reaction bottle was warmed to room temperature. The result was extracted three times using dichloromethane (CH₂Cl₂) and water as the extraction solvent. An organic phase was separated, dried, and filtrated. After concentrating by rotary evaporator, the result was purified by column chromatography, obtaining Organic metal compound (II). The synthesis pathway of the above reaction was as follows:

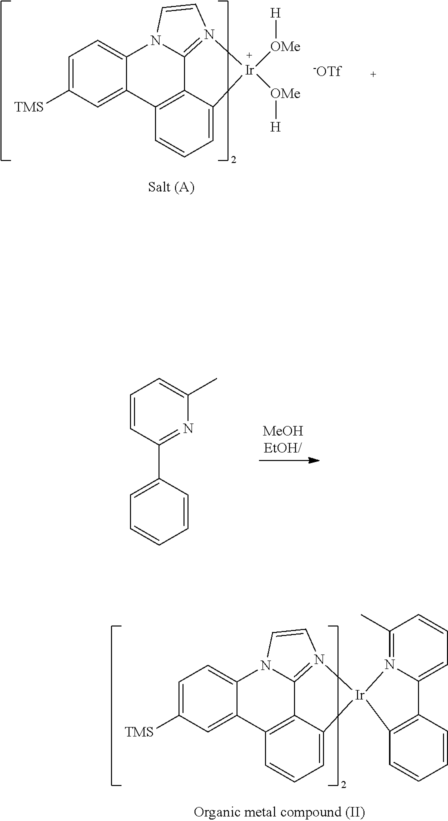

### Example 3: Preparation of Organic Metal Compound (III)

2-bromo-3-methylpyridine (0.52 g, 3 mmol), 4-fluorophenylboronic acid (0.5 g, 3.6 mmol), potassium carbonate (K₂CO₃) (0.4 g, 3 mmol), dimethoxyethane (dimethoxyethane) (20 mL), and water (10 mL) were added into the reaction bottle. Next, catalytic amount of tetrakis(triphenylphosphine) palladium (Pd(PPh₃)₄) was added into a reaction bottle. After removing moisture and purging nitrogen gas several times, the reaction bottle was heated to reflux. After reacting for 8 hours, the reaction bottle was warmed to room temperature, the result was neutralized with sodium bicarbonate (NaHCO₃) aqueous solution. The result was extracted three times using ethyl acetate (EA) and water as the extraction solvent. An organic phase was separated, dried, and filtrated. After concentrating by rotary evaporator, the result was purified by column chromatography (with ethyl acetate (EA) and n-hexane (1:40) as extraction solvent), obtaining Compound (10). The synthesis pathway of the above reaction was as follows:

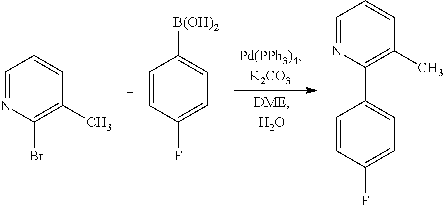

Next, Salt (A)(0.98 g, 1 mmol) and compound (10) (0.28 g, 1.5 mmol) was added into a reaction bottle, and MeOH/EtOH (10 ml, 5/5) as solvent was added into the reaction bottle. After removing moisture, drying and purging nitrogen gas several times, the reaction bottle was heated to 90° C. After reacting for 12 hours, the reaction bottle was warmed to room temperature. The result was extracted three times using dichloromethane (CH₂Cl₂) and water as the extraction solvent. An organic phase was separated, dried, and filtrated. After concentrating by rotary evaporator, the result was purified by column chromatography, obtaining Organic metal compound (III). The synthesis pathway of the above reaction was as follows:

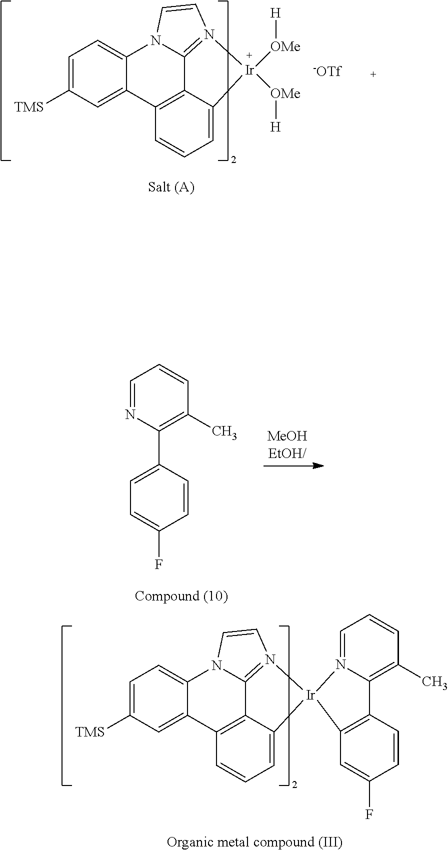

### Example 4: Preparation of Organic Metal Compound (IV)

2-bromo-6-methylpyridine (0.52 g, 3 mmol), 4-fluorophenylboronic acid (0.5 g, 3.6 mmol), potassium carbonate (K₂CO₃) (0.4 g, 3 mmol), dimethoxyethane (dimethoxyethane) (20 mL), and water (10 mL) were added into the reaction bottle. Next, catalytic amount of tetrakis(triphenylphosphine)palladium (Pd(PPh₃)₄) were added into a reaction bottle. After removing moisture and purging nitrogen gas several times, the reaction bottle was heated to reflux. After reacting for 8 hours, the reaction bottle was warmed to room temperature, the result was neutralized with sodium bicarbonate (NaHCO₃) aqueous solution. The result was extracted three times using ethyl acetate (EA) and water as the extraction solvent. An organic phase was separated, dried, and filtrated. After concentrating by rotary evaporator, the result was purified by column chromatography (with ethyl acetate (EA) and n-hexane (1:40) as extraction solvent), obtaining Compound (11). The synthesis pathway of the above reaction was as follows:

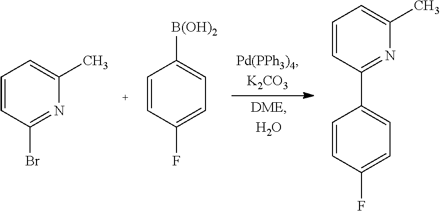

Next, compound (11) (1.23 g, 6.6 mmol), and iridium trichloride (IrCl₃) (0.89 g, 3 mmol), 2-methoxyethanol (24 ml), and water (8 ml) were added into a reaction bottle. Next, after removing moisture and purging nitrogen gas several times, the reaction bottle was heated to reflux (120° C.). After reacting for 18 hours, the reaction bottle was heated to room temperature, and then water was added into the reaction bottle. After filtrating, the filter cake was washed by water and n-hexane. After drying by a vacuum, Compound (12) was obtained. The synthesis pathway of the above reaction was as follows:

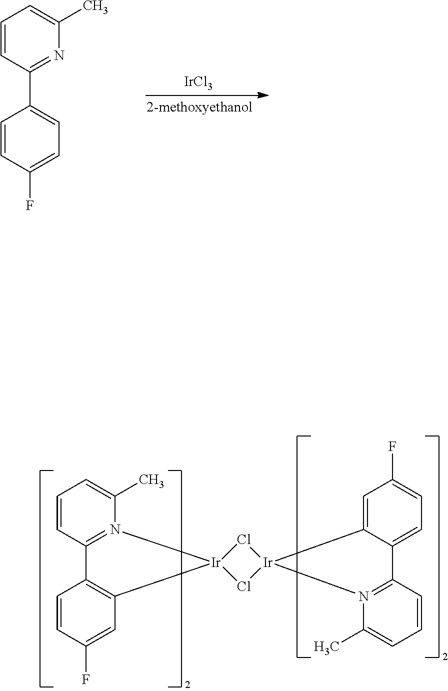

Compound (12) (1.2 g, 1 mmol), compound (7) (0.73 g, 2.5 mmol), silver trifluoromethanesulfonate (AgOTf) (silver trifluoromethanesulfonate, AgOTf) (0.56 g, 2.2 mmol), methanol (MeOH) (5 mL), and ethanol (EtOH) (5 mL) were added into a reaction bottle. Next, the mixture was stirred at 90° C. for 12 hours. After cooling to room temperature, the result was extracted three times using dichloromethane (CH₂Cl₂) and water as the extraction solvent. An organic phase was separated, dried, filtrated and concentrated by rotary evaporator. Finally, the result was purified by column chromatography (with dichloromethane/n-hexane (1:4) as the extraction solvent), obtaining Organic metal compound (IV). The synthesis pathway of the above reaction was as follows:

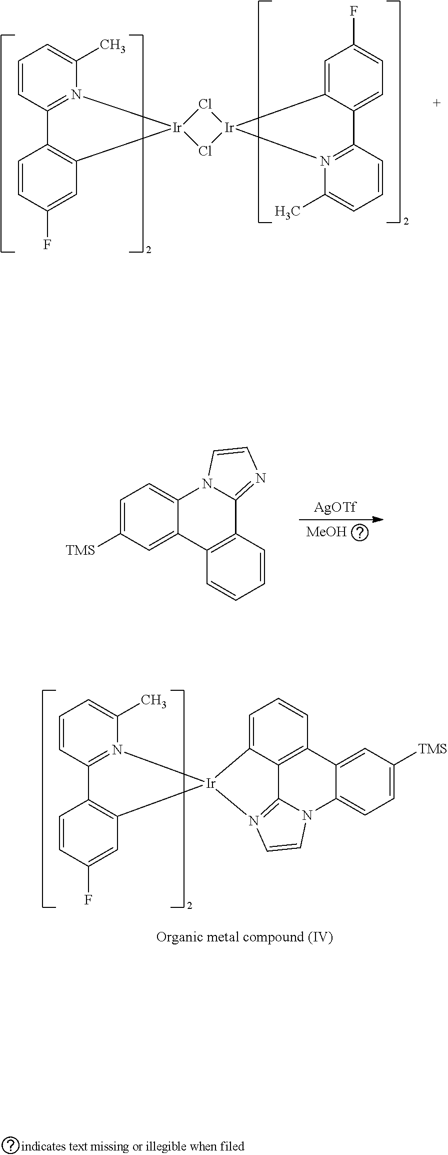

### Example 5: Preparation of Organic Metal Compound (V)

Compound (12) (1.1 g, 1 mmol), Compound (7) (0.73 g, 2.5 mmol), silver trifluoromethanesulfonate (AgOTf) (silver trifluoromethanesulfonate, AgOTf) (0.56 g, 2.2 mmol), methanol (MeOH) (5 mL) and ethanol (EtOH) (5 mL) were added into a reaction bottle. Next, the mixture was stirred at 90° C. for 12 hours. After cooling to room temperature, the result was extracted three times using dichloromethane (CH₂Cl₂) and water as the extraction solvent. An organic phase was separated, dried, filtrated and concentrated by rotary evaporator. Finally, the result was purified by column chromatography (with dichloromethane/n-hexane (1:4) as the extraction solvent), obtaining Organic metal compound (V). The synthesis pathway of the above reaction was as follows:

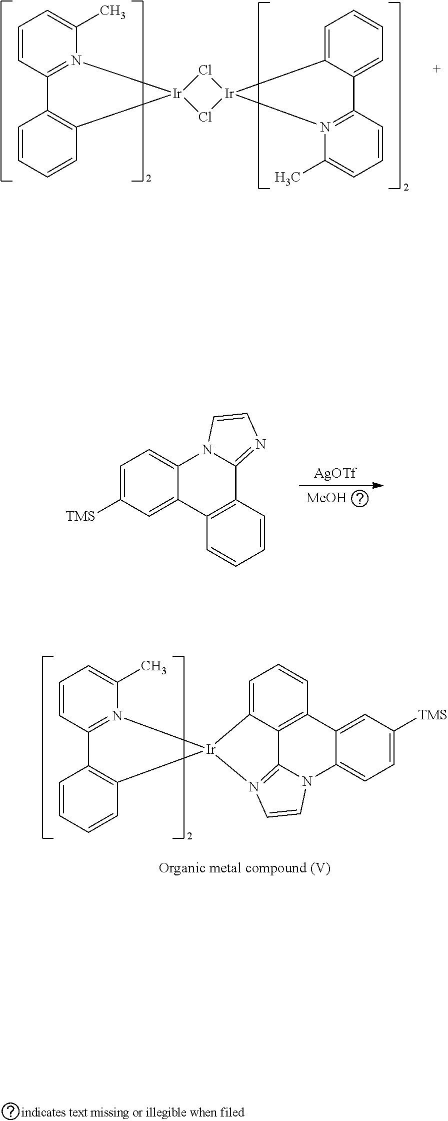

### Example 6: Preparation of Organic Metal Compound (VI)

Compound (11) (11.623 g, 62.1 mmol), potassium tert-butoxide (KOtBu) (0.697 mg, 6.2 mmol), hexadeuterodimethyl sulfoxide (DMSO-d6) (16 mL) were added into a reaction bottle. After stirring at 80° C. under nitrogen gas for 24 hours, the reaction was quenched by water, and then the result was extracted using ethyl acetate (EA) and water and purified by column chromatography (with ethyl acetate/n-hexane (1:10) as the extraction solvent), obtaining Compound (11). The synthesis pathway of the above reaction was as follows:

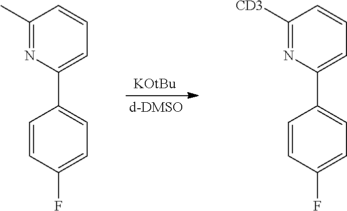 [SMILES: Cc1cccc(-c2ccc(F)cc2)n1 ; [2H]C([2H])([2H])c1cccc(-c2ccc(F)cc2)n1 ; "KOtBu"]

Next, Compound (11) (1.23 g, 6.6 mmol), and iridium trichloride (IrCl₃) (0.89 g, 3 mmol), 2-methoxyethanol (24 ml), and water (8 ml) were added into a reaction bottle. Next, after removing moisture and purging nitrogen gas several times, the reaction bottle was heated to reflux (120° C.). After reacting for 18 hours, the reaction bottle was heated to room temperature, and then water was added into the reaction bottle. After filtrating, the filter cake was washed with water and n-hexane. After drying by a vacuum, Compound (13) was obtained. The synthesis pathway of the above reaction was as follows:

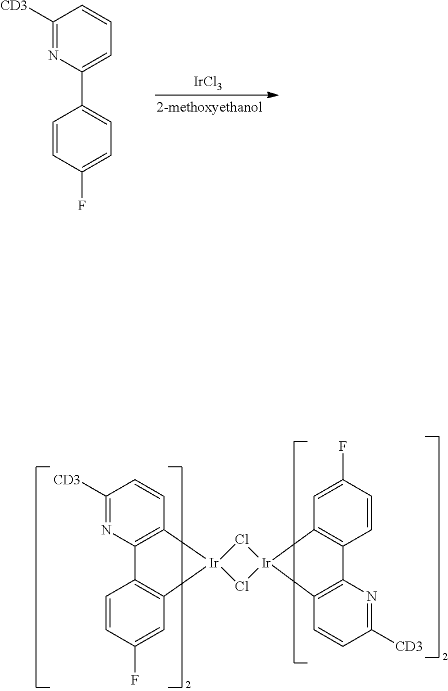

Compound (13) (1.2 g, 1 mmol), compound (7) (0.73 g, 2.5 mmol), silver trifluoromethanesulfonate (AgOTf) (silver trifluoromethanesulfonate, AgOTf) (0.56 g, 2.2 mmol), methanol (MeOH) (5 mL) and ethanol (EtOH) (5 mL) were added into a reaction bottle. Next, the mixture was stirred at 90° C. for 12 hours. After cooling to room temperature, the result was extracted three times using dichloromethane (CH₂Cl₂) and water as the extraction solvent. An organic phase was separated, dried, filtrated and concentrated by rotary evaporator. Finally, the result was purified by column chromatography (with dichloromethane/n-hexane (1:4) as the extraction solvent), obtaining Organic metal compound (VI). The synthesis pathway of the above reaction was as follows:

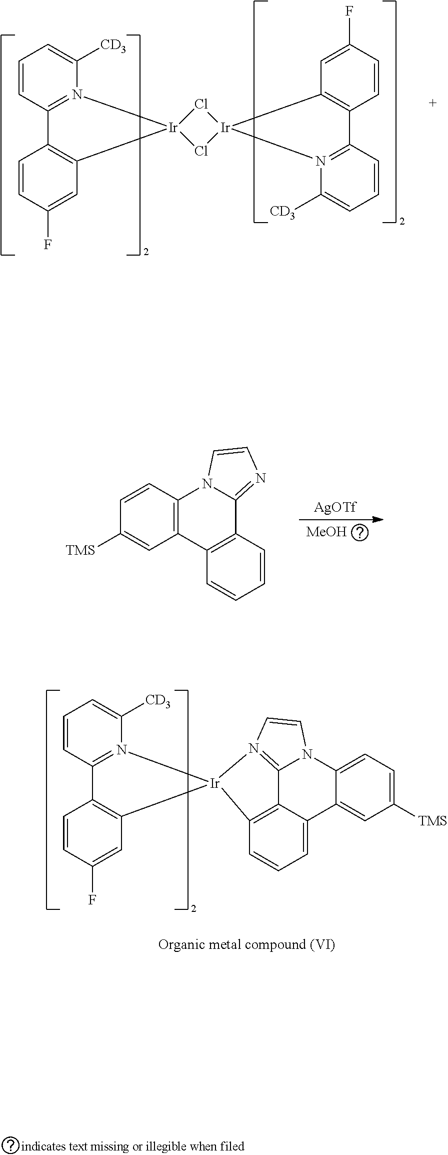

### Example 7: Preparation of Organic Metal Compound (VII)

Salt (A) (0.98 g, 1 mmol) and Compound (14) (0.26 g, 1.5 mmol) were added into a reaction bottle, and MeOH/EtOH (10 ml, 5/5) as solvent was added into the reaction bottle. After removing moisture, drying and purging nitrogen gas several times, the reaction bottle was heated to 90° C. After reacting for 12 hours, the reaction bottle was warmed to room temperature. The result was extracted three times using dichloromethane (CH₂Cl₂) and water as the extraction solvent. An organic phase was separated, dried, and filtrated. After concentrating by rotary evaporator, the result was purified by column chromatography, obtaining Organic metal compound (VII).

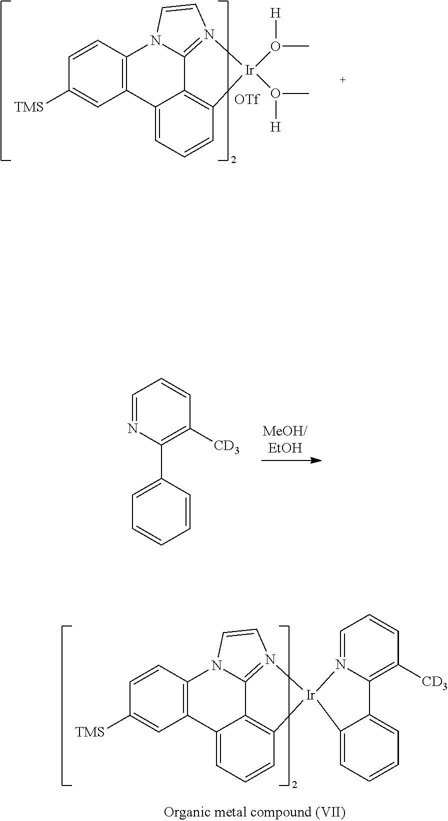

### Example 8: Preparation of Organic Metal Compound (VIII)

Salt (A) (0.98 g, 1 mmol) and Compound (12) (0.28 g, 1.5 mmol) were added into a reaction bottle, and MeOH/EtOH (10 ml, 5/5) as solvent was added into the reaction bottle. After removing moisture, drying and purging nitrogen gas several times, the reaction bottle was heated to 90° C. After reacting for 12 hours, the reaction bottle was warmed to room temperature, the result was extracted three times using dichloromethane (CH₂Cl₂) and water as the extraction solvent. An organic phase was separated, dried, and filtrated. After concentrating by rotary evaporator, the result was purified by column chromatography, obtaining Organic metal compound (VIII).

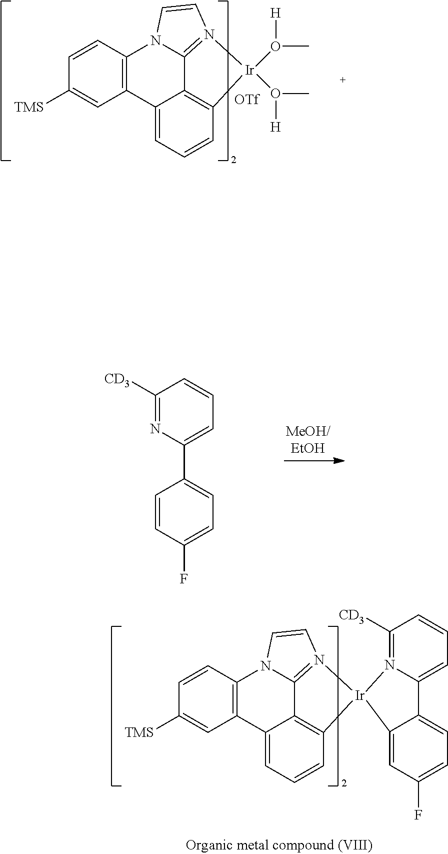

### Example 9: Preparation of Organic Metal Compound (IX)

Salt (A) (0.98 g, 1 mmol) and compound (15) (0.39 g, 1.5 mmol) were added into a reaction bottle, and MeOH/EtOH (10 ml, 5/5) as solvent was added into the reaction bottle. After removing moisture, drying and purging nitrogen gas several times, the reaction bottle was heated to 90° C. After reacting for 12 hours, the reaction bottle was warmed to room temperature, the result was extracted three times using dichloromethane (CH₂Cl₂) and water as the extraction solvent. An organic phase was separated, dried, and filtrated. After concentrating by rotary evaporator, the result was purified by column chromatography, obtaining Organic metal compound (IX).

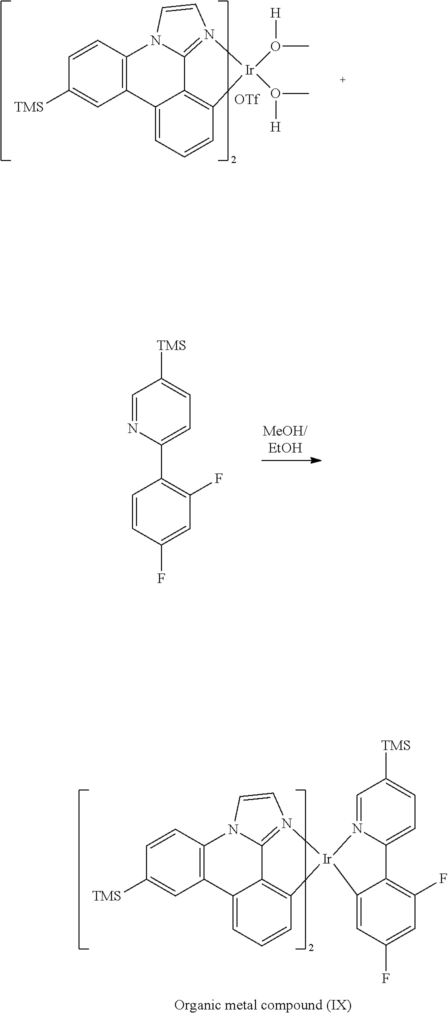

Next, the measurement results of nuclear magnetic resonance spectrometry of Organic metal compound (I)-(IX) disclosed in Examples 1-9 are shown in Table 2.

TABLE 2

| | nuclear magnetic resonance spectrum data |
|---|---|
| Organic metal compound (I) | ¹H NMR (500 MHz, CD₃OD, 294K): 7.52 (d, 6H), 6.80 (s, 3H), |
| | 6.79~6.73 (m, 6H), 6.55 (t, 3H), 6.38 (d, 3H), 6.15 (d, 3H), 0.32 |
| | (s, 27H) |
| Organic metal compound (II) | ¹H NMR (500 MHz, d-DMSO, 294K): 7.72 (d, 1H), 7.54~7.49 |
| | (m, 2H), 7.36~7.29 (m, 4H), 7.20 (t, 1H), 7.07 (t, 1H), 6.95 (d, |
| | 2H), 6.75 (d, 1H), 6.68 (t, 1H), 6.59(s, 1H), 6.44~6.36 (m, 4H), |
| | 6.22~6.09 (m, 4H), 6.01 (dd, 1H), 1.92 (s, 3H), 0.25 (s, 9H), 0.22 |
| | (s, 9H) |
| Organic metal compound (III) | ¹H NMR (500 MHz, d-DMSO, 294K): 8.30(d, 1H), 7.75 (d, 1H), |
| | 7.53 (d, 1H), 7.47 (d, 2H), 7.35~7.28 (m, 4H), 7.15 (t, 1H), 7.02 |
| | (t, 1H), 6.85 (d, 2H), 6.75 (d, 1H), 6.68 (s, 1H), 6.59(s, 1H), |
| | 6.44~6.36 (m, 3H), 6.22~6.09 (m, 3H), 1.89 (s, 3H), 0.24 (s, 9H), |
| | 0.22 (s, 9H) |
| Organic metal compound (IV) | ¹H NMR (500 MHz, CDCl₃, 294K): 8.53 (s, 1H), 7.78 (d, 1H), |
| | 7.72~7.65 (m, 2H), 7.62~7.52 (m, 3H), 7.49 (s, 1H), 7.42~7.35 |
| | (m, 2H), 7.31 (t, 1H), 7.14 (t, 1H), 6.77 (d, 1H), 6.69 (s, 1H), |
| | 6.62~6.53 (m, 3H), 6.45 (t, 2H), 6.02 (d, 1H), 1.97 (s, 3H), 1.62 |
| | (s, 3H), 0.33 (s, 9H) |
| Organic metal compound (V) | ¹H NMR (500 MHz, CDCl₃, 294K): 8.54 (s, 1H), 7.75 (d, 1H), |
| | 7.75~7.68 (m, 2H), 7.63~7.52 (m, 3H), 7.46 (s, 1H), 7.42~7.35 |
| | (m, 3H), 7.30 (t, 1H), 7.14 (t, 1H), 6.82 (d, 1H), 6.65 (s, 1H), |
| | 6.62~6.51 (m, 4H), 6.45 (t, 2H), 6.12 (d, 1H), 1.95 (s, 3H), 1.65 |
| | (s, 3H), 0.32 (s, 9H) |
| Organic metal compound (VI) | ¹H NMR (500 MHz, CDCl₃, 294K): 8.55 (s, 1H), 7.79 (d, 1H), |
| | 7.73~7.68 (m, 2H), 7.62~7.54 (m, 3H), 7.50 (s, 1H), 7.49~7.45 |
| | (m, 2H), 7.34 (t, 1H), 7.15 (t, 1H), 6.79 (d, 1H), 6.69 (s, 1H), |
| | 6.65~6.59 (m, 3H), 6.45 (t, 2H), 6.01 (d, 1H), 0.33 (s, 9H) |
| Organic metal compound (VII) | ¹H NMR (500 MHz, CDCl₃, 294K): 8.30(d, 1H), 7.65 (d, 1H), |
| | 7.53~7.42 (m, 2H), 7.35~7.27 (m, 4H), 7.22 (t, 1H), 7.11 (t, 1H), |
| | 6.89 (d, 2H), 6.72 (d, 1H), 6.68 (t, 1H), 6.55(s, 1H), 6.43~6.37 |
| | (m, 3H), 6.22~6.12 (m, 4H), 6.01 (d, 1H), 0.25 (s, 9H), 0.22 (s, |
| | 9H) |
| Organic metal compound (VIII) | ¹H NMR (500 MHz, CDCl₃, 294K): 7.73 (d, 1H), 7.52 (d, 1H), |
| | 7.45 (d, 2H), 7.33~7.22 (m, 4H), 7.15 (t, 1H), 7.10 (t, 1H), 6.84 |
| | (d, 2H), 6.73 (d, 1H), 6.70 (s, 1H), 6.55(s, 1H), 6.42~6.35 (m, |
| | 4H), 6.22~6.09 (m, 3H), 0.24 (s, 9H), 0.22 (s, 9H) |
| Organic metal compound (IX) | ¹H NMR (500 MHz, CDCl₃, 294K): 8.35 (s, 1H), 8.24 (d, 1H), |
| | 7.72 (d, 1H), 7.54~7.49 (m, 2H), 7.36~7.29 (m, 4H), 7.22 (d, 2H), |
| | 7.10(t, 1H) 6.59(s, 1H), 6.43~6.36 (m, 4H), 6.21~6.10 (m, 4H), |
| | 6.01 (dd, 1H), 0.26 (s, 9H), 0.24 (s, 9H) |

Next, Organic metal compounds (I)-(IX) of Examples 1-9 were individually dissolved into dichloromethane, obtaining solutions with a concentration of 10-5M. Next, the photoluminescence (PL) spectra of the solutions were measured, and the results are shown in Table 3.

TABLE 3

| | maximum luminous intensity |
|---|---|
| | peak (Emission λmax) |
| Organic metal compound (I) | 465 nm |
| Organic metal compound (II) | 507 nm |
| Organic metal compound (III) | 499 nm |
| Organic metal compound (IV) | 496 nm |
| Organic metal compound (V) | 510 nm |
| Organic metal compound (VI) | 494 nm |
| Organic metal compound (VII) | 499 nm |
| Organic metal compound (VIII) | 497 nm |
| Organic metal compound (IX) | 489 nm |

As shown in Table 3, the organic metal compounds of the disclosure having a structure represented by Formula (I) have a maximum luminous intensity peak between 465 nm and 510 nm (i.e. the organic metal compounds of the disclosure are greenish blue phosphorescent materials).

Next, the sublimation temperature of the organic metal compound having a structure of Formula (I) of the disclosure as disclosed in Examples were measured, and the results are shown in Table 4.

TABLE 4

| | sublimation |
|---|---|
| | temperature (° C.) |
| Organic metal compound (I) | 270 |
| Organic metal compound (II) | 265 |
| Organic metal compound (III) | 280 |
| Organic metal compound (IV) | 280 |
| Organic metal compound (V) | 275 |
| Organic metal compound (VI) | 275 |
| Organic metal compound (VII) | 280 |
| Organic metal compound (VIII) | 270 |
| Organic metal compound (IX) | 265 |

Organic Light-Emitting Device

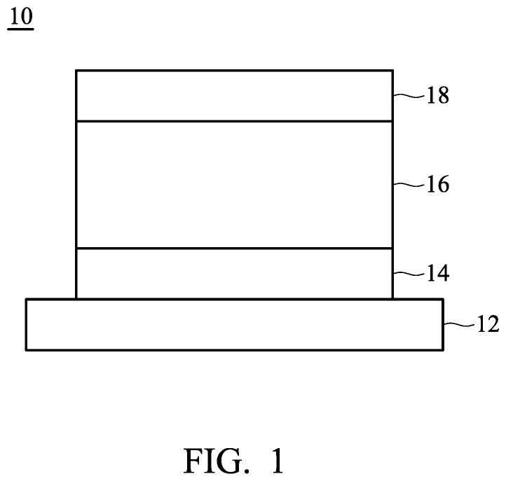

FIG. 1 shows an embodiment of an organic light-emitting device 10. The organic light-emitting device 10 includes a substrate 12, a bottom electrode 14, an organic light-emitting element 16, and a top electrode 18. The organic light-emitting device can be a top-emission, bottom-emission, or dual-emission device. The substrate 12 can be a glass, plastic, or semiconductor substrate. Suitable materials for the bottom and top electrodes can be Ca, Ag, Mg, Al, Li, In, Au, Ni, W, Pt, Cu, indium tin oxide (ITO), indium zinc oxide (IZO), aluminum zinc oxide (AZO), or zinc oxide (ZnO), formed by sputtering, electron beam evaporation, thermal evaporation, or chemical vapor deposition. Furthermore, at least one of the bottom and top electrodes 14 and 18 is transparent.

The organic light-emitting element 16 at least includes an emission layer, and can further include a hole injection layer, a hole transport layer, an electron transport layer, an electron injection layer, and/or other layers. In an embodiment of the disclosure, at least one layer of the organic light-emitting element 16 includes the aforementioned organic metal compound. Namely, in the organic light-emitting element 16, at least on of the layers of the organic light-emitting element 16 includes the organic metal compound of the disclosure.

According to another embodiment of the disclosure, the organic light-emitting device can be a phosphorescent organic light-emitting device, and the emission layer of the organic light-emitting element 16 can include a host material and a phosphorescence dopant, wherein the phosphorescence dopant can include the aforementioned organic metal compound having the structure represented by Formula (I). The emission layer emits blue or cyan light under a bias voltage. The dose of the dopant is not limited and can optionally be modified by a person of ordinary skill in the art.

In order to clearly disclose the organic light-emitting devices of the disclosure, the following examples (having an emitting layer employing the organic metal compounds of the disclosure) are intended to illustrate the disclosure more fully without limiting their scope, since numerous modifications and variations will be apparent to those skilled in this art.

### Example 10

A glass substrate with an indium tin oxide (ITO) film with a thickness of 150 nm was provided and then washed with a cleaning agent, acetone, and isopropanol with ultrasonic agitation. After drying with nitrogen flow, the ITO film was subjected to a UV/ozone treatment for 30 min. Next, PEDOT (poly(3,4)-ethylendioxythiophen):PSS (e-polystyrenesulfonate) was coated on the ITO film by a blade and spin coating process (with a rotation rate of 500 rpm for 5 sec and a rotation rate of 2000 rpm for 30 sec and) and baked at 130° C. for 10 min to form a PEDOT:PSS film serving as a hole injection layer (with a thickness of 40 nm). Next, TAPC (1,1-bis[4-[N, N′-di (p-tolyl)amino]phenyl]cyclobexane, with a thickness of 35 nm), TCTA (4, 4′, 4′-tri (N-carbazolyl)triphenylamine) doped with Organic metal compound (I) (the weight ratio between TCTA and Organic metal compound (I) was 100:6, with a thickness of 10 nm), TmPyPB (1,3,5-tri[(3-pyridyl)-phen-3-yl]benzene, with a thickness of 42 nm), LiF (with a thickness of 0.5 nm), and Al (with a thickness of 120 nm) were subsequently formed on the PEDO:PSS film at 10-6 torr, obtaining Organic light-emitting device (I) after encapsulation. The materials and layers of Organic light-emitting device (I) are described in the following: ITO/PEDOT:PSS/TAPC/TCTA:Organic metal compound (I) (6%)/TmPyPB/LiF/Al.

The optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (I) were measured by a spectra colorimeter and a luminance meter. The results are shown in Table 5.

### Example 11

Example 11 was performed in the same manner as in Example 10 except that Organic metal compound (IV) was substituted for Organic metal compound (I), obtaining Organic light-emitting device (II). The materials and layers of Organic light-emitting device (II) are described in the following: ITO/PEDOT:PSS/TAPC/TCTA:Organic metal compound (IV) (6%)/TmPyPB/LiF/Al.

The optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (II) were measured by a spectra colorimeter and a luminance meter. The results are shown in Table 5.

### Example 12

Example 12 was performed in the same manner as in Example 10 except that Organic metal compound (VII) was substituted for Organic metal compound (I), obtaining Organic light-emitting device (III). The materials and layers of Organic light-emitting device (III) are described in the following: ITO/PEDOT:PSS/TAPC/TCTA:Organic metal compound (VII) (6%)/TmPyPB/LiF/Al.

The optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (III) were measured by a spectra colorimeter and a luminance meter. The results are shown in Table 5.

### Example 13

Example 13 was performed in the same manner as in Example 10 except that Organic metal compound (IX) was substituted for Organic metal compound (I), obtaining Organic light-emitting device (IV). The materials and layers of Organic light-emitting device (IV) are described in the following: ITO/PEDOT:PSS/TAPC/TCTA:Organic metal compound (IX) (6%)/TmPyPB/LiF/Al.

The optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (IV) were measured by a spectra colorimeter and a luminance meter. The results are shown in Table 5.

### Comparative Example 1

Comparative Example 1 was performed in the same manner as in Example except that Compound (15) (having a structure of

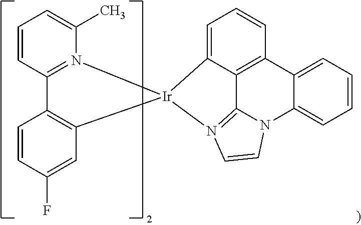

was substituted for Organic metal compound (I), obtaining Organic light-emitting device (V). The materials and layers of Organic light-emitting device (V) are described in the following: ITO/PEDOT:PSS/TAPC/TCTA: Compound (15) (6%)/TmPyPB/LiF/Al.

The optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (V) were measured by a spectra colorimeter and a luminance meter. The results are shown in Table 5.

### Comparative Example 2

Comparative Example 2 was performed in the same manner as in Example 10 except that Compound (16) (having a structure of

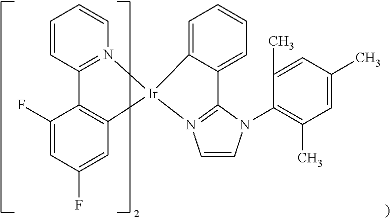

was substituted for Organic metal compound (I), obtaining Organic light-emitting device (VI). The materials and layers of Organic light-emitting device (VI) are described in the following: ITO/PEDOT:PSS/TAPC/TCTA: Compound (16) (6%)/TmPyPB/LiF/Al.

The optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (VI) were measured by a spectra colorimeter and a luminance meter. The results are shown in Table 5.

TABLE 5

| | | | current | power | | Emis- |
|---|---|---|---|---|---|---|
| | volt- | bright- | effi- | effi- | | sion |
| | age | ness | ciency | ciency | C.I.E | λmax |
| | (V) | (cd/m2) | (cd/A) | (lm/W) | coordinate | (nm) |
| Example 10 | 4.5 | 1000 | 30.0 | 26.0 | (0.18, 0.36) | 469 |
| Example 11 | 4.8 | 1000 | 32.2 | 21.1 | (0.22, 0.57) | 496 |
| Example 12 | 4.2 | 1000 | 39.1 | 29.5 | (0.22, 0.58) | 496 |
| Example 13 | 4.9 | 1000 | 30.3 | 19.3 | (0.19, 0.51) | 488 |
| Comparative | 4.5 | 1000 | 25.5 | 20.3 | (0.24, 0.55) | 498 |
| Example 1 | | | | | | |
| Comparative | 4.9 | 1000 | 17.2 | 11.0 | (0.25, 0.53) | 499 |
| Example 2 | | | | | | |

As shown in Table 5, since the trimethylsilyl group is introduced into the organic metal compound, the HOMO (highest occupied molecular orbital) energy gap of the organic metal compound matches the conventional transport material. In comparison with the organic light-emitting device of Comparative Example 1, the organic light-emitting device employing the organic metal compound of the disclosure exhibits higher luminescent efficiency.

It will be clear that various modifications and variations can be made to the disclosed methods and materials. It is intended that the specification and examples be considered as exemplary only, with the true scope of the disclosure being indicated by the following claims and their equivalents.

What is claimed is:

1. An organic metal compound, having a structure of Formula (I): 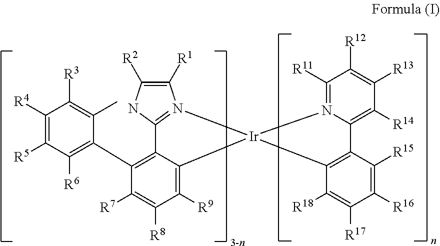
wherein R¹ or R² is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸ or R⁹ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ are independently C₁₋₈ alkyl group; R¹¹, R¹², R¹³, R¹⁴, R¹⁵, R¹⁶, R¹⁷, or R¹⁸ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ are independently C₁₋₈ alkyl group; and n meets one of following conditions (1), (2) and (3):
(1) n is 0, and at least one of R³, R⁴, R⁵, R⁶, R⁷, R⁸ and R⁹ is —Si(R¹⁹)₃, wherein R¹⁹ are independently C₁₋₈ alkyl group;
(2) n is 1 or 2, and at least one of R³, R⁴, R⁵, R⁶, R⁷, R⁸, R⁹, R¹¹, R¹², R¹³ and R¹⁴ is —Si(R¹⁹)₃, wherein R¹⁹ are independently C₁₋₈ alkyl group; and
(3) n is 3, and at least one of R¹¹, R¹², R¹³, and R¹⁴ is —Si(R¹⁹)₃, wherein R¹⁹ are independently C₁₋₈ alkyl group.

2. The organic metal compound as claimed in claim 1, wherein R¹ or R² is independently hydrogen, deuterium, deuterated methyl, deuterated ethyl, fluorine, methyl group, ethyl group, propyl group, isopropyl group, butyl group, sec-butyl group, iso-butyl group, tert-butyl group, pentyl group, hexyl group, fluoromethyl group, fluoroethyl group, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

3. The organic metal compound as claimed in claim 1, wherein R³, R⁴, R⁵, R⁶, R⁷, R⁸, R⁹, R¹¹, R¹², R¹³, R¹⁴, or R¹⁵ are independently hydrogen, deuterium, deuterated methyl, deuterated ethyl, fluorine, methyl group, ethyl group, propyl group, isopropyl group, butyl group, sec-butyl group, iso-butyl group, tert-butyl group, pentyl group, hexyl group, fluoromethyl group, fluoroethyl group, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, naphthyl group, or trimethylsilyl group.

4. The organic metal compound as claimed in claim 1, wherein R¹⁶, R¹⁷, or R¹⁸ is independently hydrogen, fluorine, methyl group, ethyl group, propyl group, isopropyl group, butyl group, sec-butyl group, iso-butyl group, tert-butyl group, pentyl group, hexyl group, fluoromethyl group, fluoroethyl group, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

5. The organic metal compound as claimed in claim 1, wherein R¹⁹ are independently methyl group, ethyl group, propyl group, n-butyl group, sec-butyl group, iso-butyl group, tert-butyl group, pentyl group, or hexyl group.

6. The organic metal compound as claimed in claim 1, wherein the organic metal compound is 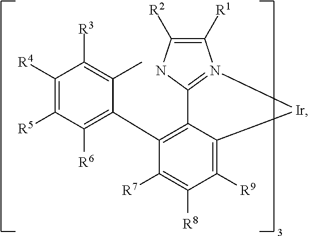
wherein R¹ or R² is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; and R³, R⁴, R⁵, R⁶, R⁷, R⁸, or R⁹ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ are independently C₁₋₈ alkyl group; and at least one of R³, R⁴, R⁵, R⁶, R⁷, R⁸, and R⁹ is —Si(R¹⁹)₃.

7. The organic metal compound as claimed in claim 1, wherein the organic metal compound is 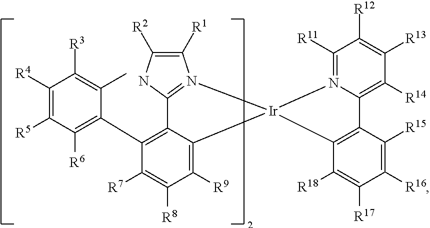
wherein R¹ or R² is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹¹, R¹², R¹³, R¹⁴, or R¹⁵ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ are independently C₁₋₈ alkyl group; and R¹⁶, R¹⁷, or R¹⁸ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; and at least one of R³, R⁴, R⁵, R⁶, R⁷, R⁸, R⁹, R¹¹, R¹², R¹³, R¹⁴, and R¹⁵ is —Si(R¹⁹)₃.

8. The organic metal compound as claimed in claim 1, wherein the organic metal compound is 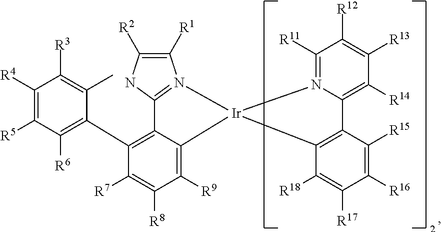
wherein R¹ or R² is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹¹, R¹², R¹³, R¹⁴, or R¹⁵ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ are independently C₁₋₈ alkyl group; and R¹⁶, R¹⁷, or R¹⁸ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; and at least one of R³, R⁴, R⁵, R⁶, R⁷, R⁸, R⁹, R¹¹, R¹², R¹³, R¹⁴, and R¹⁵ is —Si(R¹⁹)₃.

9. The organic metal compound as claimed in claim 1, wherein the organic metal compound is 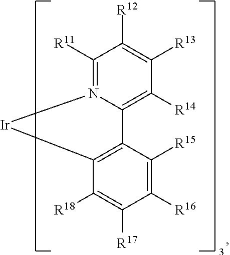
wherein R¹⁵, R¹⁶, R¹⁷, or R¹⁸ is independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, or C₆₋₁₂ aryl group; R¹¹, R¹², R¹³, or R¹⁴ are independently hydrogen, deuterium, C₁₋₈ alkyl group, C₁₋₈ deuterated alkyl group, halogen, C₁₋₈ haloalkyl group, C₁₋₈ alkoxy group, C₅₋₁₀ cycloalkyl group, C₆₋₁₂ aryl group, or —Si(R¹⁹)₃, and at least one of R¹¹, R¹², R¹³, and R¹⁴ is —Si(R¹⁹)₃; and R₁₉ are independently C₁₋₈ alkyl group.

10. An organic light-emitting device, comprising:
a pair of electrodes; and
an organic light-emitting element, disposed between the electrodes, wherein the organic light-emitting element comprises the organic metal compound as claimed in claim 1.
